(19) United States
(12) Patent Application Publication
(10) Pub. No.: US 2010/0078313 A1
(43) Pub. Date: Apr. 1, 2010

(54) SPUTTERING APPARATUS AND METHOD OF THIN FILM FORMATION

(75) Inventors: Toshinobu Chiba, Kawasaki-shi (JP); Katsuya Yoshioka, Kawasaki-shi (JP)

Correspondence Address: FITZPATRICK CELLA HARPER & SCINTO, 1290 Avenue of the Americas, NEW YORK, NY, 10104-3800, US

(73) Assignee: CANON ANELVA CORPORATION, Kawasaki-shi (JP)

(21) Appl. No.: 12/540,693

(22) Filed: Aug. 13, 2009

Related U.S. Application Data
(63) Continuation of application No. PCT/JP2008/067736, filed on Sep. 30, 2008.

(51) Int. Cl. C23C 14/34

(52) U.S. Cl. 204/192.12; 204/298.15; 204/298.07

(57) ABSTRACT

The present invention provides a sputtering apparatus and a method of thin film formation, whereby a film having quality superior in uniformity even for relatively large substrates can be obtained and the generation of particles and nodules is suppressed. The sputtering apparatus of the present invention includes: a vacuum vessel (9); a substrate holder (7) for supporting a substrate (6); a cathode mechanism located opposite to the substrate (6); and a second gas introduction mechanism for introducing a gas into the vacuum vessel (9). The cathode mechanism has a plurality of targets (1a) to (1c) arranged with a gap formed between each other and a plurality of backing plates (2a) to (2c) arranged with a gap formed between each other. A gap (14) between each of the targets is smaller than a gap (15) between each of the backing plates. In addition, the gap (14) overlaps with at least part of the gap (15). The second gas introduction mechanism introduces a gas through the gap (15) and the gap (14).

### CROSS-REFERENCES TO RELATED APPLICATIONS

This application is a continuation application of International Application No. PCT/JP2008/067736, filed on Sep. 30, 2008, the entire contents of which are incorporated by reference herein.

### TECHNICAL FIELD

The present invention relates to a sputtering apparatus and a method of thin film formation and, more particularly, to a sputtering apparatus and a method of thin film formation whereby a film having quality superior in uniformity is obtained and particle generation from a target is suppressed.

### BACKGROUND ART

In reactive sputtering in a sputtering apparatus, a reactive gas, such as oxygen or nitrogen, is introduced along with an inert gas, such as argon, in order to cause sputtering to take place within a vacuum chamber. In such reactive sputtering, particles of a target material are knocked out as the result of argon ions in generated plasma impinging on the target material. The particles of the target material react with the abovementioned reactive gas, and a film formed of a reactant generated by the reaction deposits on a substrate. In addition, if the concentration of the reactive gas is high, a surface of the target material reacts with the reactive gas to form a compound layer. As the result of these substances being sputtered, a reactant having a desired composition deposits on the substrate.

In the case of a conventional sputtering apparatus, gas introduction into a vacuum chamber is performed from near a wall of the vacuum chamber. A gas concentration within the vacuum chamber is kept uniform until plasma is generated. However, once the plasma is generated, a reactive gas reacts with sputter atoms in the plasma and is thus consumed. Therefore, the reactive gas is high in concentration around the plasma but low in the central part thereof. In addition, as described above, gas introduction is performed near a wall of the vacuum chamber. Accordingly, even if the reactive gas is supplied in succession, the reactive gas is first consumed by reaction outside the plasma. Thus, a concentration gradient of the reactive gas may arise between the outside and inside of the plasma. As a result, there may arise the problem that the quality of a film deposited on a substrate differs between the central part and the peripheral part thereof.

Hence, several proposals have been made in the past, in order to solve the above-described problems.

According to Patent Document 1, there is disclosed a sputtering apparatus in which a gas is also introduced from a plurality of small holes provided in a target material or a plurality of small holes provided in an interposition member interposed on a division surface of a divided target, as well as from a conventional gas introduction port (gas introduction port provided near a wall of the vacuum chamber).

Patent Document 1: Japanese Patent Application Laid-Open No. H5-320891

### DISCLOSURE OF THE INVENTION

However, although the method shown in Patent Document 1 is an effective technique as the distribution of the reactive gas in the plasma can be made uniform, the method has the below-described problems that remain to be solved. First, in a method for introducing a gas by creating small holes in the target material itself, which is one form disclosed in Patent Document 1, the target material which is a consumable needs to be machined, thus causing running costs to increase. In addition, small holes also need to be created in a backing plate, thus requiring significantly high precision when the target material having small holes is bonded. Such problems as described above become increasingly serious, as substrates and targets are increased in size.

Next, in a method for introducing a gas from a plurality of small holes provided in the interposition member interposed on the division surface of a divided target, which is another form disclosed in Patent Document 1, a voltage is also applied to the interposition member at the time of sputtering for reasons of apparatus configuration. Consequently, not only the target material but also the interposition member is sputtered and, therefore, substrates may be contaminated.

In addition, as substrates and targets are increased in size in a parallel plate-type sputtering apparatus, backing plates also become inevitably larger. On the other hand, it is difficult to make a large backing plate as an integral component as a matter of manufacturing methods or operations. Accordingly, a method is employed, for example, in which a backing plate increased in size (also called a large-sized backing plate) by putting together a plurality of members (also called backing plate elements) is formed, and the large-sized backing plate is attached to the apparatus. However, gaps among backing plate elements serve as a source of particle generation and can be a cause for the generation of nodules in the case of transparent conductive films, such as an ITO film. That is, particles accumulate in the gaps among the respective backing plates, and the accumulated particles pile up to form nodules in the gaps. A progress in the generation of nodules causes such problems as a drop in the rate of thin film formation and an increase in the frequency of arc discharge. This in turn leads to shutting down the apparatus to do the work of removing the nodules, thus degrading manufacturing efficiency. In addition, the nodules may cause additional particles to be generated, and the additional particles may, for example, adhere to a film formed on a substrate, thus possibly causing the quality of the film to degrade.

An object of the present invention is to solve the above-described problems and provide a sputtering apparatus and a method of thin film formation, whereby a film having quality superior in uniformity even for relatively large substrates can be obtained and the generation of particles and nodules is suppressed.

A first aspect of the present invention is a sputtering apparatus including: a vacuum vessel; a substrate holder located inside the vacuum vessel to support a substrate; a plurality of backing plates arranged opposite to the substrate holder to support a plurality of targets; and a gas introduction mechanism for introducing a gas into the vacuum vessel; wherein the plurality of backing plates are arranged with a first gap formed between each other, and the gas introduction mechanism introduces a gas through the first gap.

A second aspect of the present invention is a method of thin film formation of forming a thin film on a substrate using a sputtering apparatus according to the first aspect, including a step of arranging the plurality of targets on the plurality of backing plates with a gap formed between each other, wherein the plurality of targets are arranged on the plurality of backing plates so that a second gap between each of the targets is smaller than a first gap between each of the backing plates, and the second gap overlaps with at least part of the first gap.

According to the present invention, a gas distribution within plasma is uniformized and it is reduced that members for supporting the targets are sputtered. Consequently, it is possible to form a film having quality superior in uniformity on a substrate, and reduce substrate contamination.

In addition, as the result of introducing a gas from a gap between each of a plurality of backing plates used due to an increase in the sizes of substrates and targets, particles are less likely to accumulate in the gap. Thus, it is possible to suppress the generation of particles and nodules.

### BRIEF DESCRIPTION OF THE DRAWINGS

FIG. 1 is a cross-sectional side view illustrating a sputtering apparatus in accordance with one embodiment of the present invention;

FIG. 2 is a front view of divided backing plates and targets in accordance with one embodiment of the present invention;

FIG. 3 is a front view of a partition plate provided with an insulating plate in accordance with one embodiment of the present invention;

FIG. 4 is a cross-sectional front view of a partition plate in accordance with one embodiment of the present invention; and

FIG. 5 is a front view illustrating a partition plate in accordance with one embodiment of the present invention.

### BEST NODES FOR CARRYING OUT THE INVENTION

Hereinafter, embodiments of the present invention will be described in detail with reference to the accompanying drawings. Note that components having the same functions are denoted by like reference numerals in the drawings to be explained hereinafter and repetitive descriptions will be omitted.

### First Embodiment

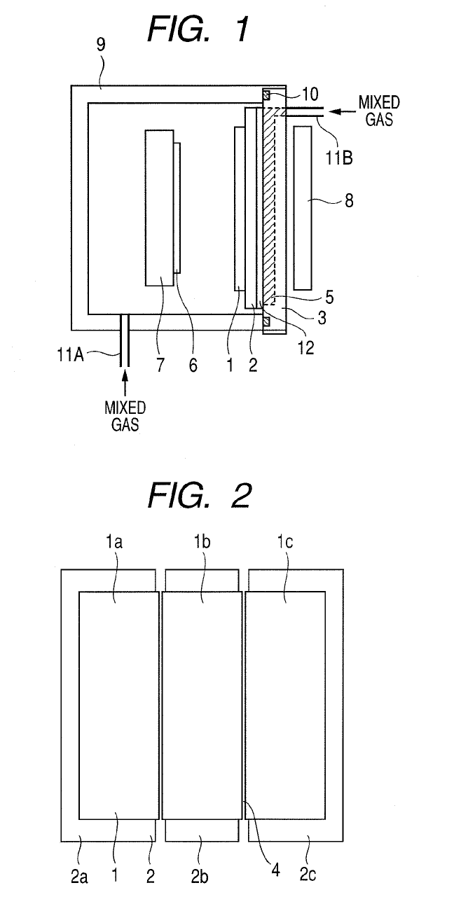

Hereinafter, a sputtering apparatus in accordance with one embodiment of the present invention will be described using FIGS. 1 to 5.

FIG. 1 is a cross-sectional side view illustrating a schematic configuration of a sputtering apparatus in accordance with a first embodiment of the present invention. This sputtering apparatus includes a vacuum vessel 9, a substrate holder 7 provided inside the vacuum vessel 9 to support a substrate, and a cathode mechanism located opposite to the substrate. This cathode mechanism has a backing plate 2 for supporting a target 1. The target 1 is supported onto this backing plate 2.

In addition, a first gas introduction mechanism for introducing a gas from a gas supply pipe 11A to the vacuum vessel 9 and a second gas introduction mechanism for introducing a gas from a gas introduction pipe 11B to the vacuum vessel 9 are provided in the sputtering apparatus. The first gas introduction mechanism is located separately from the backing plate 2 of the vacuum vessel 9. The second gas introduction mechanism is used to supply a gas from the backing plate.

The backing plate 2 is attached through an insulating plate 12 to a partition plate 3 serving as a support member. The partition plate 3 is attached, using unillustrated bolt members, to the vacuum vessel 9 forming a space in which sputtering is performed (hereinafter referred to as the film-forming chamber). The partition plate 3 and the vacuum vessel 9 are vacuum-sealed using an O-ring 10. A magnet 8 is located on the atmospheric side of the partition plate 3.

Note that in the present embodiment, the partition plate 3 and the vacuum vessel 9 are coupled with each other using the O-ring 10. However, without limitation to this, the partition plate 3 and the vacuum vessel 9 may be coupled with each other using, for example, an adhesive agent or bolts and nuts. Thus, any members or materials may be used as long as the partition plate 3 and the vacuum vessel 9 can be coupled with each other.

FIG. 2 is a front view illustrating a condition in which the target 1 is attached to the backing plate 2.

As illustrated in FIG. 2, the target 1 has three target members (sub-targets), targets 1a, 1b and 1c, arranged at predetermined intervals. In the present specification, a group of the targets 1a, 1b and 1c is referred to as the target 1. In addition, the backing plate 2 has three backing plates (sub-backing plates), backing plates 2a, 2b and 2c, arranged at predetermined intervals. In the present specification, a group of the backing plates 2a, 2b and 2c is referred to as the backing plate 2. The targets 1a to 1c may be formed by dividing one target or may be separate targets. Likewise, the backing plates 2a to 2c may be formed by dividing one backing plate or may be separate backing plates. Use of separate backing plates is preferred, however, since it is possible to easily cope with sputtering to large-sized substrates.

FIG. 4 is a cross-sectional front view illustrating a condition in which the target 1 and the backing plate 2 are provided on the partition plate 3. The backing plate 2 and the target 1 are attached to the partition plate 3 through an insulating plate 12. Gas introduction grooves 5 are provided in the partition plate 3. The gas introduction grooves 5 are formed as trenches on the insulating plate 12 side of the partition plate 3. Part of each gas introduction groove 5 is connected to the gas supply pipe 11B for introducing a gas into the vacuum vessel 9.

FIG. 5 is a front view illustrating the partition plate 3 provided with the gas introduction grooves 5.

Note that in the present embodiment, the partition plate 3 is provided as a member separate from the vacuum vessel 9 and is coupled with the vacuum vessel 9 using the O-ring 10 or the like serving as connection means. However, without limitation to this, the partition plate 3 and the vacuum vessel 9 may be integrated with each other. That is, a predetermined wall of the vacuum vessel 9 may be allowed to function as the partition plate 3. In this case, a mechanism of connection between each gas introduction groove 5 and the gas introduction pipe 11B may be formed on the predetermined wall of the vacuum vessel 9.

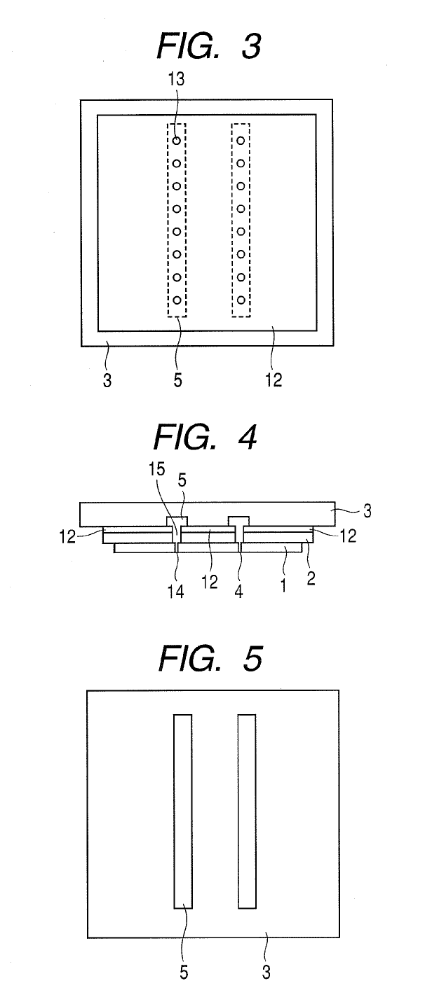

FIG. 3 is a front view illustrating a condition in which the insulating plate 12 is attached to the partition plate 3. A plurality of holes (through-holes) 13 are provided in the insulating plate 12. The holes 13 of the insulating plate 12 are provided in positions communicated with the gas introduction grooves 5 (dashed lines) on the back side of the insulating plate. That is, the holes 13 are positioned so as to let a gas supplied to the gas introduction grooves 5 pass through.

Note that in the present embodiment, a gas is supplied from gas introduction pipe 11B side to the film-forming chamber side through the gas introduction grooves 5 and the holes 13, separately from the gas introduction pipe 11A located near a wall of the vacuum vessel 9. That is, a gas is supplied from the holes 13 formed in the predetermined positions of a cathode mechanism within a region where plasma is generated. With a gas supplied from these holes 13 into the film-forming chamber, it is possible to reduce the concentration gradient of a gas, such as a reactive gas. Accordingly, arranging the plurality of holes 13 along the longitudinal direction of each gas introduction groove 5, as illustrated in FIG. 3, is preferred since it is possible to uniformly supply a gas into the region where plasma is generated and further uniformize the abovementioned concentration gradient. Even if only one hole 13 is formed, however, it is still possible to supply a gas into generated plasma. Thus, it is possible to reduce the abovementioned concentration gradient by a corresponding amount. As described above, in the present embodiment, it is possible to attain the above-described advantage by forming at least one hole 13 so that the gas introduction grooves 5 and the film-forming chamber are communicated with each other.

The respective backing plates 2a to 2c composing the backing plate 2 are arranged on the insulating plate 12 with a gap formed between each other. At this time, the respective backing plates 2a to 2c are arranged so as not to block all of the holes 13 formed in the insulating plate 2. That is, the backing plates 2a to 2c are positioned so that a gap 15 between each of the backing plates 2a to 2c overlaps with some of the holes 13. In addition, a gap 14 between each of the targets 1a to 1c overlaps at least part of the gap 15 since a gas passing through the gap 15 needs to be introduced into the film-forming chamber. By forming the gap 14 and the gap 15 in this way, it is possible to supply a gas introduced from each gas introduction groove 5 into the film-forming chamber.

In addition, the respective targets 1a to 1c composing the target 1 are arranged on the backing plate 2 with a gap serving as a gas ejection port 4 formed between each other. The target 1 is provided on the backing plate 2 so that the gap 14 between targets is smaller than the gap 15 between backing plates. By making the gap 14 smaller than the gap 15 in this way, it is possible to let the targets 1a to 1c function as masks against plasma, thereby preventing the backing plates 2a to 2c from being exposed to plasma. Accordingly, it is possible to prevent the backing plates from being sputtered and reduce substrate contamination.

The gap 14 between targets is preferably 0.2 mm or larger but not larger than 1.0 mm. By setting this gap to 1.0 mm or smaller, it is possible to prevent sputter particles from bypassing through the gap. In addition, by setting the gap to 0.2 mm or larger, it is possible to prevent gas ejection out of the holes 13 from being blocked at gas flow rates in a commonly-used range.

Note that in the present embodiment, the backing plate 2 is a group of the vertically triparted backing plates 2a, 2b and 2c (sub-backing plates) and the target 1 is a group of the targets 1a, 1b and 1c (sub-targets), as illustrated in FIG. 2. However, the number and the size of the sub-backing plates and the sub-targets may changed arbitrarily.

In addition, in the above-described embodiment, holes serving as gas supply ports are provided in the insulating plate. Alternatively, a plate-like body may be used without limitation to the insulating plate.

The gas introduction mechanism 5 is connected to the gas introduction pipe 11B on the atmospheric side by way of the gas introduction grooves provided in the partition plate 3. Accordingly, it is possible to reduce a distance between the target 1 and the magnet 8 even in cases where a gas introduction path is provided between the target 1 and the magnet 8, so as to supply a gas into generated plasma. Thus, it is possible to increase a magnetic field strength on a surface of the target 1. Here, the magnet 8 is preferably able to swing in parallel and laterally with respect to the target 1, in order to enhance the utilization efficiency of the target 1.

Thin film formation in a reactive sputtering apparatus having the above-described configuration is carried out by following steps described hereinafter. First, the targets 1a to 1c are located on the backing plates 2a to 2c arranged at predetermined intervals, as illustrated in FIGS. 2 and 4. That is, the targets 1a to 1c are disposed on the backing plates 2a to 2c so that a gap between each of the targets 1a to 1c is smaller than a gap between each of the backing plates 2a to 2c, and that the gap between each of the targets 1a to 1c overlaps with at least part of the gap between each of the backing plates 2a to 2c.

Next, an inert gas, such as argon, and a reactive gas, such as nitrogen or oxygen, are previously flow-controlled using an MFC (mass flow controller) or the like, so as to have a predetermined pressure, and then supplied as a mixed gas from the gas introduction pipes 11A and 11B. Introduction of the above-described mixed gas is performed simultaneously from a first gas introduction mechanism whereby a gas is introduced directly into the vacuum vessel, and from a second gas introduction mechanism whereby a gas is introduced, by way of the gas introduction grooves 5 inside the partition plate 3, from the gas ejection port 4 through the gaps included in the backing plate 2 and the target 1 into the vacuum vessel 9.

Next, electric power is applied to the target 1 using a DC power supply or the like to perform reactive sputtering, thereby forming a film on a substrate 6 opposite to the target 1. Note that the electric power is supplied from the DC power supply to the target 1, by way of the partition plate 3, using a power supply path penetrating through the insulating plate.

Note that in the above-described embodiment, the first gas introduction mechanism and the second gas introduction mechanism are provided in the vacuum vessel, and the mixed gas containing an inert gas and a reactive gas is supplied from the respective gas introduction mechanisms. It is not essential, however, to introduce the mixed gas from both the first gas introduction mechanism and the second gas introduction mechanism. The essence of the present invention is to uniformize the concentration gradient of the reactive gas in a region where plasma is generated. In the present invention, it is possible to reduce the concentration gradient of the reactive gas if the reactive gas is supplied from the second gas introduction mechanism. In addition, since at least a reactive gas is supplied from the second gas introduction mechanism, only an inert gas for sputtering a target may be introduced from the first gas introduction mechanism. That is, at least a reactive gas may be supplied from the second gas introduction mechanism and at least an inert gas may be supplied from the first gas introduction mechanism.

As described above, in the present embodiment, the plurality of backing plates 2a to 2c and the plurality of targets 1a to 1c are arranged with gaps provided thereamong, the gas introduction grooves 5 connected to the gas introduction pipe 11B are formed along the longitudinal direction of these gaps, and the gaps 14 and 15 are formed so as to let a gas supplied from the gas introduction grooves 5 pass through. Accordingly, a reactive gas can be supplied from a region within a target to a region between a cathode mechanism and the substrate 6. Thus, it is possible to reduce the concentration gradient of the reactive gas in a region of generated plasma. Consequently, it is possible to uniformize the quality of a film to be formed on the substrate.

Conventionally, a plurality of backing plates have been arranged in order to increase the size of substrates or targets. Accordingly, there have been cases in which particles accumulate in gaps among the backing plates and serve as a source of particle generation. In the present embodiment, however, gaps among backing plates are allowed to function as part of a gas introduction path. Accordingly, accumulation of particles in the abovementioned gaps decreases, thereby making it possible to suppress the generation of nodules and particles.

Furthermore, in the present embodiment, a plurality of backing plates and a plurality of targets are used, and part of a gas introduction path is formed by utilizing gaps formed when these backing plates and targets are arranged. Accordingly, it is possible to supply a gas to a region between the cathode mechanism and the substrate without the need for carrying out machining to create holes in targets and backing plates or provide an interposition member as in Patent Document 1. Consequently, it is possible to carry out reactive sputtering at reduced costs. In addition, by arranging the backing plates and the targets as described above without the need for applying the abovementioned machining, it is possible to form a gas introduction path. Accordingly, it is possible to use existing backing plates and targets without the need for machining, and easily increase the sizes of substrates and targets.

### Second Embodiment

In the first embodiment, an explanation has been made of a form which includes both the first gas introduction mechanism and the second gas introduction mechanism. In the present embodiment, an explanation will be made of a form in which the first gas introduction mechanism is not provided.

When a mixed gas containing an inert gas and a reactive gas is introduced from the second gas introduction mechanism, both the inert gas and the reactive gas are introduced between the cathode mechanism inside the vacuum vessel 9 and the substrate 6. In addition, the second gas introduction mechanism is designed to supply a gas, so as to reduce the concentration gradient of the reactive gas in a region between the cathode mechanism and the substrate 6, which is a region where plasma is generated. Accordingly, the inert gas and the reactive gas are supplied to the region where plasma is generated, without the need for providing the first gas introduction mechanism including the gas introduction pipe 11A. In addition, it is possible to uniformize the concentration gradient of the reactive gas.

As described above, in the present embodiment, when the mixed gas is supplied from the second gas introduction mechanism, if the first gas introduction mechanism is not provided in the vacuum, it is possible to realize the same advantage as that of the first embodiment, if.

Having thus described the preferred modes and embodiments of the present application with reference to the accompanying drawings, the present invention is not limited to these modes and embodiments, but may be modified into various other forms within the technical scope understood from the description of the scope of the appended claims.

What is claimed:

1. A sputtering apparatus comprising:
a vacuum vessel;
a substrate holder located inside said vacuum vessel to support a substrate;
a plurality of backing plates arranged opposite to said substrate holder to support a plurality of targets; and
a gas introduction mechanism for introducing a gas into said vacuum vessel;
wherein said plurality of backing plates are arranged with a first gap formed between each other, and
said gas introduction mechanism introduces a gas through said first gap.

2. The sputtering apparatus according to claim 1, further comprising a plurality of targets arranged on said plurality of backing plates with a second gap formed between each other,
wherein said plurality of targets are arranged on said plurality of backing plates so that a second gap between each of said targets is smaller than a first gap between each of said backing plates and said second gap overlaps with at least part of said first gap, and
said gas introduction mechanism introduces a gas through said first gap and said second gap.

3. The sputtering apparatus according to claim 1, further comprising:
an insulating plate which is located on a surface of said backing plates opposite to a surface thereof for supporting said targets and has at least one through-hole; and
a support member which is located on a surface of said insulating plate opposite to a surface thereof whereon said backing plates are arranged, and in which a groove is formed;
wherein said insulating plate is located on a surface of said support member in which said groove is formed; and
said gas introduction mechanism introduces said gas by way of said groove, said through-hole, and said first gap in this order.

4. The sputtering apparatus according to claim 2, wherein said second gap is within the range from 0.2 mm to 1.0 mm.

5. The sputtering apparatus according to claim 1, wherein a gas introduced by said gas introduction mechanism into said vacuum vessel is a mixed gas containing an inert gas and a reactive gas.

6. The sputtering apparatus according to claim 1, further comprising another gas introduction mechanism provided separately from said gas introduction mechanism and designed to introduce a gas from a position separate from said backing plates.

7. The sputtering apparatus according to claim 6, wherein at least an inert gas is introduced from said gas introduction mechanism and at least a reactive gas is introduced from said separate gas introduction mechanism.

8. The sputtering apparatus according to claim 7, wherein a mixed gas containing said inert gas and said reactive gas is introduced from said gas introduction mechanism and said separate gas introduction mechanism.

9. A method of thin film formation of forming a thin film on a substrate using a sputtering apparatus according to claim 1, comprising
a step of arranging said plurality of targets on said plurality of backing plates with a gap formed between each other, wherein said plurality of targets are arranged on said plurality of backing plates so that a second gap between each of said targets is smaller than a first gap between each of said backing plates, and said second gap overlaps with at least part of said first gap.

10. The method of thin film formation according to claim 9, wherein said introduced gas is a mixed gas containing an inert gas and a reactive gas.

11. The method of thin film formation according to claim 9, wherein the sputtering apparatus further comprises another gas introduction mechanism provided separately from said gas introduction mechanism and designed to introduce a gas from a position separate from said gas introduction mechanism,
wherein at least an inert gas is introduced from said gas introduction mechanism and at least a reactive gas is introduced from said separate gas introduction mechanism.

12. The method of thin film formation according to claim 11, wherein a mixed gas containing said inert gas and said reactive gas is introduced from said gas introduction mechanism and said separate gas introduction mechanism.

13. The method of thin film formation according to claim 12, wherein said mixed gas is simultaneously introduced from said gas introduction mechanism and said separate gas introduction mechanism.

14. A method of manufacturing a substrate by forming a thin film thereon using a sputtering apparatus according to claim 1, comprising the steps of:
holding a substrate on said substrate holder; and
supplying a gas to the substrate by introducing the gas through said first gap.

15. A method of manufacturing a substrate by forming a thin film thereon using a sputtering apparatus according to claim 2, comprising the steps of:
holding a substrate on said substrate holder; and
supplying a gas to the substrate by introducing the gas through said first gap and said second gap.

16. The method of manufacturing a substrate according to claim 14, wherein said introduced gas is a mixed gas containing an inert gas and a reactive gas.

17. The method of manufacturing a substrate according to claim 16, wherein the sputtering apparatus further comprises another gas introduction mechanism provided separately from said gas introduction mechanism and designed to introduce a gas from a position separate from said gas introduction mechanism,
wherein at least an inert gas is introduced from said gas introduction mechanism and at least a reactive gas is introduced from said separate gas introduction mechanism.

18. The method of manufacturing a substrate according to claim 17, wherein a mixed gas containing said inert gas and said reactive gas is introduced from said gas introduction mechanism and said separate gas introduction mechanism.

19. The method of manufacturing a substrate according to claim 18, wherein said mixed gas is simultaneously introduced from said gas introduction mechanism and said separate gas introduction mechanism.
